(19) United States
(12) Patent Application Publication
(10) Pub. No.: US 2024/0021712 A1
(43) Pub. Date: Jan. 18, 2024

(54) A NOVEL TRANSISTOR DEVICE

(71) Applicant: Search For The Next, LTD, Nottingham (GB)

(72) Inventors: David SUMMERLAND, Nottingham Nottinghamshire (GB); Roger LIGHT, Nottingham Nottinghamshire (GB); Luke KNIGHT, Nottingham Nottinghamshire (GB)

(21) Appl. No.: 18/256,727

(22) PCT Filed: Dec. 9, 2021
(86) PCT No.: PCT/GB2021/053234

§ 371 Date: Jun. 9, 2023

(30) Foreign Application Priority Data
Dec. 9, 2020 (GB) 2019401.5
Nov. 8, 2021 (GB) 2116047.8

(51) Int. Cl. H01L 29/735; H01L 29/66; H01L 29/73; H01L 29/08; H01L 29/10; H01L 27/082; H01L 21/3205

(52) U.S. Cl. CPC H01L 29/735; H01L 29/66931; H01L 29/6625; H01L 29/7302; H01L 29/0808; H01L 29/0821; H01L 29/1008; H01L 27/082; H01L 21/32055

(57) ABSTRACT

A bipolar transistor having a semiconductor structure that includes a channel of semiconductor type that is the same as the collector and emitter regions. The channel is significantly shallower than the base region with which it interfaces. The semiconductor structure provides improved current gain. It also enables the device to operate, when on, selectively either with primarily unipolar conduction or with primarily bipolar conduction by control of the voltage across the emitter and collector terminals of the transistor.

### CROSS-REFERENCE TO RELATED APPLICATIONS

This application claims priority from and is related to the following prior application Patent Cooperation Treaty Patent PCT/GB2021/053234, filed on 9 Dec. 2021, which claims priority to Great Britain Patent Application No. 2019401.5, filed on 9 Dec. 2020, and which claims priority to Great Britain Patent Application No. 2116047.8, filed on 8 Nov. 2021. These prior applications, including the entirety of their written description and drawings, are collectively hereby incorporated by reference into the present application.

### BACKGROUND

The present invention relates to a novel transistor having, among other advantages, improved current gain characteristics over conventional lateral bipolar junction transistors (BJTs).

For headphones specially intended to be worn in bed and/or while the wearer is sleeping, it is desirable the headphones are as comfortable as possible when worn lying down in order that they do not interfere with the wearer's sleep or ability to fall asleep.

The semiconductor structure and doping configuration of a BJT is such that current between the emitter and collector (the controlled current) is a consequence of movement of both electron and electron hole charge carriers, referred to as bipolar conduction.

In contrast in a field effect transistor (FET) or Junction Field Effect transistor (JFET) current between the source and drain terminals (the controlled current) is primarily, if not solely, attributable to movement of either electrons or electron holes but not both, referred to as unipolar conduction or single-carrier-type operation.

US6251716B1, US200316704A1 and US2009206375 are examples of known JFET configurations and thus current between the source and drain is primarily attributable to unipolar conduction.

### BRIEF SUMMARY

According to a first aspect of the invention there is provided a transistor device having: a collector region provided by a first region of semiconductor of a first type; a collector terminal associated with the collector region; an emitter region provided by a second region of semiconductor of the first type; an emitter terminal associated with the emitter region; a base region provided by a third region of semiconductor lying between and interfacing with both the collector region and emitter region; a base terminal associated with the base region; wherein the base region includes: a sub-region of semiconductor of a second type; and a channel of semiconductor of the first type; wherein the base terminal contacts the sub-region; the sub-region interfaces with the channel to provide a first diode junction, and interfaces with both the emitter region and the collector region to form further diode junctions, and the channel interfaces with and interconnects the collector region and the emitter region such that when the device is implemented in a circuit in a first condition, namely where a voltage is placed across the emitter and collector terminals that is above a first threshold voltage, and the base terminal is floating or shorted to the emitter terminal, a current between the collector and emitter terminals is at least predominately attributable to unipolar conduction; the net doping concentration of the channel is less than the net doping concentration of the emitter and collector regions; and that the channel has a depth extending away from the first diode junction which is sufficiently small that when the device is implemented in a circuit in a second condition, namely where the voltage placed across the emitter and collector terminals is below the first threshold voltage, and the base terminal is floating or shorted to the emitter terminal, a depletion region is formed about the first diode junction sufficient to pinch the channel so that substantially no current between the collector and emitter terminals of the device; and where the device is implemented in a circuit in a third condition namely, where there is voltage is placed across the emitter and collector terminals, and there is a voltage across the emitter and base terminals such as to cause current through the base terminal, the current between the collector and emitter terminals is at least predominantly attributable to bipolar conduction.

By virtue of the presence of the channel, in what is otherwise a substantially conventional BJT semiconductor structure, the device can be operated either as a normally ON device or a normally OFF device depending on the voltage applied across the emitter and collector terminals.

The value of the threshold voltage is tied with the length of the channel that extends between the emitter and collector regions and typically thus also the separational distance between the emitter region and collector region. Consequently, for an anticipated emitter-collector voltage range, it is possible to fabricate the transistor device to operate either as normally ON or normally OFF by selecting the length of the channel.

The same mask process can be used to define the spacing for all transistor devices in the circuit. Advantageously, this makes it possible to fabricate an integrated circuit comprising both normally ON and normally OFF transistors without additional processing steps. Such circuits can be used to perform functions that would usually require use of complementary transistors, e.g., NMOS & PMOS, that require more semiconductor layers and/or production steps to implement. Applications that may benefit from this advance include logic gate circuits, analogue comparators and op-amp circuits.

When operating in the first condition, where the voltage placed across emitter and collector terminals (Vce) is greater than the first threshold, the transistor device functions as a normally ON device; the channel allows for unipolar conduction between the collector and emitter terminals, notwithstanding that there is no current through the base terminal.

When operating in the second condition, where the voltage across the emitter and collector terminals is below the first threshold value, the very small depth of the channel (a function of the small depth of the semiconductor layer that provides the channel) means that a depletion region, which exists about the first diode junction, is sufficient that the channel has a high enough resistance to prevent current through the channel.

It can be thought that where Vce is greater than the threshold, it is large enough to overcome the depletion region allowing for a current between the emitter and collector. As the length of the channel increases, the value of Vce needed to overcome the depletion region also increases.

The very small absolute depth of the channel, as well as its relatively small depth compared with that of the sub-region of the base, means that where operated in the third condition, i.e., where the voltage across the emitter and base terminals (Vbe) is greater than the forward bias voltage of the base-emitter diode junction Vft, a majority of the current through the base terminal will be attributed to bipolar conduction through the emitter and sub-base regions rather than through the channel.

Notwithstanding, when operating in the third condition the presence of the channel provides the transistor with improved gain characteristics compared with BJT transistors with conventional structures. This is thought to be because the channel provides a conduction path between the emitter and collector regions without crossing a diode junction and which thus provides relatively low resistance.

A consequence of the manner in which the transistor device functions is that as the value of Vbe changes above Vft, the proportion of Ice attributable to bipolar conduction and unipolar conduction changes and thus the current gain of the transistor changes; as the proportion of bipolar conduction increases the current gain drops.

A further unexpected but advantageous feature of the novel transistor design is that it allows, through selection of the channel length for a known operating range for Vce, a normally OFF transistor that switches ON at values of Vbe below the forward bias voltage of the base emitter diode junction.

Expressed another way, when operated in a fourth condition in which the voltage across the emitter and collector terminals is between the first threshold (Vt) and a second threshold (Vt′), where |Vt′|<|Vt|, the transistor device, which operates as a normally OFF transistor, switches ON when Vbe is less that the forward bias voltage (Vft) of the base emitter diode junction.

When operating in the fourth condition, current between the emitter and collector is a result of unipolar conduction through the channel and consequently the device has a higher gain compared with when operating in the fourth condition albeit with a smaller maximum current between the emitter and collector.

The transistor device, where adapted to switch between OFF and the fourth condition, has a channel which is too long, when Vbe=0, for a Vce of a value less than Vt to overcome the depletion region about the first diode junction. Nevertheless, the channel is short enough that application of a small forward voltage across the base and emitter terminals (Vbe greater than 0), whilst not being enough to overcome a depletion region about the base emitter diode junction (Vbe<Vft), and thus Ibe=0, is enough to weaken the intrinsic depletion region about the first diode junction to an extent to allow current between the emitter and collector via the channel. The minimum value of Vbe required to operate the transistor device in the fourth condition will depend on the value of Vce and Vt for that transistor device.

An application where this has utility includes a driver circuit where it is advantageous for first stage transistors to have reduced bipolar conduction (i.e., greater unipolar conduction—possibly solely unipolar conduction) to provide higher gain, whereas second stage transistors have increased bipolar conduction to allow for higher current rating whilst minimizing the surface (plane) area of the device.

Advantageously, the presence of the channel allows for the transistor device to switch between ON (operating in first or fourth conditions) and OFF in response to a change in Vbe that is less than the absolute value of the forward voltage of the base-emitter diode (Vft). This allows, for example, two transistor devices of the same configuration, e.g., both NPN or both PNP, to be used to switch both sides (high and low) of a driver circuit, rather than the conventional requirement for a complementary pair.

A suitable depth for the channel will depend on the values of Vce at which the transistor is designed to operate and/or the doping concentration of the channel.

For example, for a transistor adapted to operate at voltages between 0V and |5V|, a channel depth below 0.25 μm and favorably 0.1 μm or less may be suitable.

Nevertheless, for a given operating voltage, the maximum depth of the channel permitted will be notably smaller than would exist for a JFET designed to operate at a comparable operating voltage.

In contrast, the depth of the sub-region extending in the opposite direction from the first diode junction may be equal or greater than five times that of the channel. In some embodiments the depth of the sub-region may be at least twenty time that of the channel.

The sub-region may comprise a first portion and a second portion, and wherein: the first portion has a higher net doping concentration than the second portion; the base terminal electrically connects to the second portion through the first portion; and in which the second portion interfaces with the channel to provide the first diode junction, and interfaces with both the emitter region and the collector region to form the further diode junctions. This ensures that a relatively high doped region can be used at the base contact to provide an ohmic contact, whilst a lower doped region interfaces with the channel, emitter and collector regions.

Ensuring predominately bipolar conduction when operating within the third condition requires careful selection of the net doping concentrations of the emitter region, collector region and sub-region of the base, as well as the spacing between the emitter and collector regions, also known as the base width. The exact values will depend on variables such as the expected operating voltage ranges of Vce and Vbe and the semiconductor fabrication process size and material used. The approach used to select values for these variables is the same and common practice for designing a conventional BJT structure and so will be readily understood by the person skilled in the art.

The net doping concentration of the channel may be equal to or less than (e.g. between 0.1 and 1 times) the net doping concentration of sub-region. This ensures the depletion region at the first diode junction preferentially exists within the channel compared within the sub-region. For example, where the channel is comprised from P type semiconductor material and the sub region is comprised from an N type semiconductor material, the net doping concentration of P type dopant in the channel may be between 0.1 and 1 times the net concentration of N type dopant within the sub region.

To provide good conduction characteristics within the first part of the sub region, the first part of the sub-region may have a net doping concentration between 1e16 per cm3 and 5e17 per cm3 inclusive.

Good bipolar conduction characteristics also depend on a relatively small lateral separation between the collector and emitter regions, therefore the lateral separation between the collector and emitter regions may be less or equal to 1.5 microns.

The emitter and/or collector regions may lie at least partly within the sub-region of the base.

According to another aspect of the invention there is provided a transistor device having: a collector region provided by a first region of semiconductor of a first type; a collector terminal associated with the collector region; an emitter region provided by a second region of semiconductor of the first type; an emitter terminal associated with the emitter region; a base region provided by a third region of semiconductor lying between and interfacing with both the collector region and emitter region; a base terminal associated with the base region wherein the base region includes: a sub-region of semiconductor of a second type; and a channel of semiconductor of the first type; wherein the sub-region interfaces with the channel to provide a diode junction and the channel interfaces with and interconnects the collector region and the emitter region; the net doping concentration of the channel is less than the net doping concentration of the emitter and collector regions; and that the channel has a depth extending away from the diode junction which is sufficiently small compared with the sub-region that when the device is implemented in a circuit where a voltage is placed across emitter and collector terminals, and the base terminal is floating or shorted to the emitter terminal, a depletion region is formed about the PN junction sufficient to pinch the channel so that substantially no current flows between the collector and emitter terminals of the device.

The sub-region of the base may be formed in a semiconductor substrate layer of the first type. The substrate can thus provide the function of isolating multiple separate integrated devices.

To minimize effects of a parasitic transistor formed by the combination of the substrate, sub-region and collector and/or emitter regions, the device may further comprise a highly doped region of the second type of semiconductor lying between, so as to separate, the sub-region from the substrate; the highly doped region having a high net doping concentration compared with the sub-region.

The emitter region and collector region may be provided, at least in part, by a polysilicon layer. The pattern of doped polysilicon may lie on a surface of a silicon die in which the base region is formed.

The emitter region may have a higher net doping concentration than the collector region. Alternatively, the net doping concentration of the emitter region and collector region may be the substantially the same.

### BRIEF DESCRIPTION OF THE DRAWINGS

The accompanying figures in which like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which

FIG. 1 is a schematic cross-section of a semiconductor structure implementing a transistor;

FIG. 2 is a chart illustrating how the operating characteristics of the transistor device of FIG. 1 varies with changes in Vbe and Vce;

FIG. 3A is a schematic cross-section of the device of FIG. 1 showing the transistor configured in an ON condition and in which conduction between the emitter and collector is primarily attributable to bipolar conduction;

FIG. 3B is a schematic cross-section of the device of FIG. 1 showing the transistor configured in an OFF condition;

FIG. 3C is a schematic cross-section of the device of FIG. 1 showing the transistor configured in an ON condition and in which conduction between the emitter and collector is primarily attributable to unipolar conduction;

FIG. 4A is a schematic cross-section of a transistor device similar to FIG. 1 but with a shorter spacing X, configured in an ON condition in which current between the emitter and collector is primarily attributable to unipolar conduction;

FIG. 4B is a schematic cross-section of the transistor device of FIG. 4A showing the transistor configured in an OFF condition;

FIG. 5A is a schematic cross-section of a variant semiconductor structure to implement a transistor device;

FIG. 5B is a plan view of the transistor implemented by the semiconductor structure illustrated in FIG. 5A; and

FIGS. 6A-6I are schematic representations illustrating process stages for the manufacture of the transistor device of FIGS. 5A and 5B.

### DETAILED DESCRIPTION

As required, detailed embodiments are disclosed herein; however, it is to be understood that the disclosed embodiments are merely examples and that the devices and methods described herein can be embodied in various forms. Therefore, specific structural and functional details disclosed herein are not to be interpreted as limiting, but merely as a basis for the claims and as a representative basis for teaching one of ordinary skill in the art to variously employ the disclosed subject matter in virtually any appropriately detailed structure and function. Further, the terms and phrases used herein are not intended to be limiting, but rather, to provide an understandable description. Additionally, unless otherwise specifically expressed or clearly understood from the context of use, a term as used herein describes the singular and/or the plural of that term.

The terms “a” or “an”, as used herein, are defined as one or more than one. The term “plurality”, as used herein, is defined as two or more than two. The term “another”, as used herein, is defined as at least a second or more. The terms “including” and “having,” as used herein, are defined as comprising i.e., open language. The term “coupled,” as used herein, is defined as “connected,” although not necessarily directly, and not necessarily mechanically.

It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

Reference in the specification to “one embodiment” or “an embodiment” of the

present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

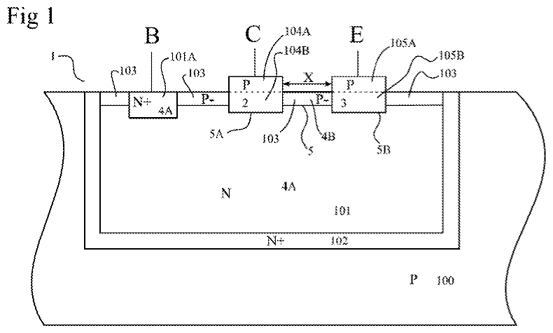

With reference to FIG. 1 there is shown a novel transistor device 1. The transistor device 1 was conceived as an improvement to bipolar junction transistor (BJT) devices and in certain aspects operates in a similar fashion. For this reason, the terminals of the device 1 are referred to using BJT nomenclature.

The device 1, which in this example is of a PNP type and is not shown to scale, is comprised from semiconductor material doped to provide a collector region 2, an emitter region 3 and a base region 4. The base region 4 lies between the collector region 2 and emitter region 3.

The collector region 2 and emitter region 3 are both of P type semiconductor, and as is conventional, the emitter region 3 may be more heavily doped than the collector region 2. For example, the net doping concentration of the collector region 2 may be greater or equal to 1×10¹⁸ cm⁻³, and the net doping concentration at the emitter region 3 may be greater or equal to 2×10¹⁸ cm⁻³. Alternatively, for ease of manufacture, they may instead have substantially the same net doping concentration. A collector terminal C is connected to the collector region 2, an emitter terminal E to the emitter region 3, and a base terminal B to the base region 4.

In contrast with a conventional BJT the base region 4 of the transistor device 1 is comprised from two regions of different type semiconductor: a first region of N type material, herein after the N type base region 4A, and second region, hereafter referred to as the channel 4B, of P type material.

The base terminal B connects to the base region 4 through the N type region 4A. The N type base region 4A directly interfaces with the channel 4B to form a PN junction 5. The N type base region 4A directly interfaces with both the collector region 2 and emitter region 3.

The channel 4B extends between and directly interfaces with the collector region 2 and emitter region 3. The channel 4B has a very weak net doping concentration compared with that of the collector region 2 and emitter region 3. For example, the net doping concentration of the channel may be less or equal to 5×10¹⁶ cm⁻³.

Further, the channel 4B is formed to have a depth, i.e., dimension extending orthogonally from NP junction 5, which is significantly shallower than is conventional with junction field effect transistor (JFET).

The subregion is comprised from a first part and a second part. The net concentration of N dopant in the first part may be around 1e17/cm3. The net doping concentration in the second part may be, for example, about 1e18/cm3 or 1e19/cm3.

Below describes the semiconductor structure implementing the above mentioned features.

There is provided a P type substrate 100, which may be, for example, a silicon wafer or layer deposited by epitaxy on top of the wafer. Within the substrate 100 is provided an N type region 101. Separating the N type region 101 from the substrate 100 is an N+region 102. Within the N type region 101 is provided a further N+region 101A that extends to a surface of the substrate material. The N type region 101 and further N+region 101A constitute the N type base region 4A of the transistor device 1, with the base contact B connected via the further N+ region 101A. The net concentration of N dopant in the N region 101 may be around 1e17/cm3. The net doping concentration of the N+ region 102 and further N+ region 101A may be, for example, about 1e18/cm3 or 1e19/cm3.

Extending across the top of the N region 101 is a lightly doped P− region 103 that provides channel 4B and interfaces with the N region 101 to provide the diode junction 5. The structure also includes two separated P regions 104, 105. A first part 104A, 105A of each P region 104, 105 is provided by respective separate portions of a P doped polysilicon layer. A second part 104B, 105B of each P region 104, 105 is formed in the silicon wafer and interfaces the N region 101 to provide respective diode junctions 5A 5B.

An example manufacturing process for the semiconductor structure is described. A first implant and diffusion process is used with a first mask to form the N+ region 102 in the P type substrate 100. Using a second mask the N region 101 is formed by counter doping the N+ region 101 with P dopant whereupon the N region 101 extends to the surface of the wafer.

Preferably without using a mask, the surface of the wafer is further doped with P dopant to form the P− layer 103 across the surface of the wafer. The net doping concentration of the P− region 103 may, for example, be 5e16/cm3 or less. The depth of the P− region 103 is kept very small by ensuring little or no diffusion takes place. The relative thickness of the P-layer 103 compared with the other layers is exaggerated in FIG. 1 for intelligibility.

Using a third mask, N dopant is implanted through the wafer surface counter doping a portion of the P− region 103 to form the further N+ region 101A so that it is contiguous with the N region 101.

Using a forth mask, a layer of polysilicon material is deposited and etched to provide portions 104A 105A of the collector and emitter regions 2, 3. Using a fifth mask the polysilicon material is doped with P dopant and diffused downward to form second parts 104B 105B that interface with the N region 101.

Implantation of P dopant is followed by a short anneal, e.g. 10 seconds, to repair the crystal structure of the polysilicon and silicon wafer.

Modes of Operation

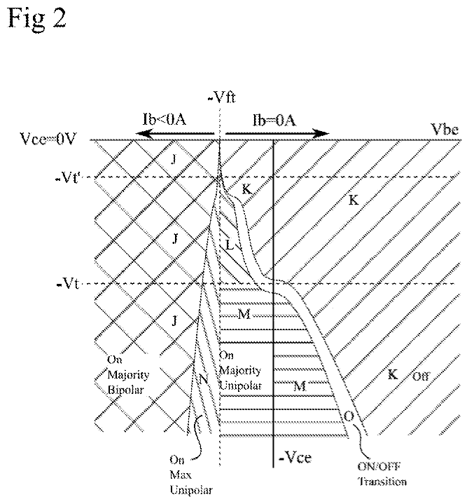

With reference to FIG. 2, the operating characteristics or modes of the device of FIG. 1 alter depending on the voltage across the collector terminal and emitter terminal (Vce) and the voltage across the base terminal and emitter terminal (Vbe).

With a PNP device, such as the one shown in FIG. 1, irrespective of the mode of operation, it is normally operated with a negative Vce, i.e., the voltage applied to the collector is more negative than the voltage applied to the emitter, and Vbe may be either positive or negative with a negative base-emitter junction forward threshold voltage Vft. Any current through the base terminal will be negative (in other words current is drawn out through the base terminal). In contrast, a NPN device is normally operated with a positive Vce, has a positive Vft, and any current through the base will be positive (in other words current is pushed into the device through the base).

Five modes of operation are shown labelled K, J, L M & N. When the device is OFF and there is no current through any terminal, the device is operating in region K. When the device is ON it may operate in one of modes J, L, M and N.

When the device is ON (i.e., there a current between the collector and emitter) and there is no or deminimus current through the base terminal (i.e., Ib=0A), excluding any temporary switching current due to capacitance effects, the device is operating in regions L or M. When the device is ON (i.e., there is a non-zero current between the collector and emitter) and there is current through the base terminal (i.e., Ib<0A), the device is operating in regions J or N.

Operation with |Vce|<|Vt|

When the transistor device 1 operates with |Vce| smaller than |Vt|, the transistor device 1 functions as a normally OFF device. In other words, there is no current between the emitter 2 and collector 3 (the device is OFF (operating in (K) region)) when Vbe is zero.

If |Vbe| is increased such that the base-emitter diode junction 5B becomes forward biased (i.e., for a PNP transistor, Vbe becomes more negative than −Vft; for a NPN transistor, Vbe becomes more positive than Vft), then the device switches ON, operating in the ON Majority Bipolar region J, where current is drawn through the base terminal and the current between the collector and emitter is attributed in the majority to bipolar conduction.

Alternatively, if |Vbe| is increased in the opposite direction such that the base-emitter diode junction 5B becomes more reverse biased (i.e., for a PNP transistor, Vbe becomes more positive; for a NPN transistor, Vbe becomes more negative), then the device remains OFF (operating in region (K)).

Where |Vce| is greater than |Vt′| and less than |Vt|, the device operates in a similar manner as when |Vce| is less than |Vct′|, with the exception that as |Vbe| approaches but is less than |Vft|, the device enters the ON Majority Unipolar operating region L where the device is ON with zero current through the base terminal and the current between the collector and emitter is attributed in the majority to unipolar conduction.

As |Vbe| becomes greater than |Vft|, it enters a transition region N where the unipolar conduction current is at a maximum, and bipolar conduction current increases until bipolar conduction current is greater than unipolar conduction current whereupon the device operates in the ON majority bipolar conduction region J.

Advantageous a normally OFF device can be switched ON and operated in region L at a lower Vbe than existing BJTs, and, advantageously, lower than the base emitter diode junction forward voltage (Vft). When operating within L region the device has significantly higher current gain but lower magnitude of maximum collector current compared to operating within the region J for the same Vce. Because of the significantly lower Vbe the device when operating in the L region has a significantly higher current gain that existing BJTs—near infinite gain as there is substantially zero current through the base terminal.

Operation With |Vce|>|Vt|

When the transistor device 1 is operated with |Vce| greater than a threshold voltage |Vt|, the transistor device 1 functions as a normally ON device. In other words, there is more than a de minimis current between the emitter and collector when Vbe is zero, e.g. because the base terminal is floating or tied to the emitter.

When |Vce| is greater than |Vt| and Vbe is at or around zero, the transistor operates in the ON majority unipolar operating region M where there is zero current through the base terminal and the current between the collector and emitter is attributed in the majority to unipolar conduction.

As |Vbe| increases above Vft, such that the base-emitter diode junction 5B becomes forward biased (i.e., for a PNP transistor, Vbe becomes more negative than −Vft; for a NPN transistor, Vbe becomes more positive than Vft), then the device operates in the transition region N where unipolar conduction is at a maximum and the bipolar conduction increases. As |Vbe| increases further, the proportion of Ice that can be attributed to bipolar conduction becomes greater than that attributed to unipolar conduction current whereupon operation is ON Majority Bipolar (region J).

The magnitude of Vbe needed to operate in the J region increases with increasing magnitude of Vce.

Alternatively, if |Vbe| is increased in the opposite direction such that the base-emitter diode junction 5B becomes more reverse biased (i.e., for a PNP transistor, Vbe becomes more positive; for a NPN transistor, Vbe becomes more negative), then the device will switch OFF (operate region K).

Between the OFF region K and the ON Majority Unipolar regions L and M is a transition region O where the operation of the device is unpredictable or difficult to control. For example, if the collector current in the OFF region K is less than 1 nA, and the collector current in the ON regions L and M is on the order of 1uA or greater, then the collector current within the transition region O will be of the order of 10 nA to 100 nA.

The device 1 has a lateral spacing between the collector region 2 and emitter region 3 of distance X which governs the length of the channel 4B. The values of Vt and Vt′ are correlated to the spacing X between the emitter and collector regions. As the value of X increases, the magnitude of |Vt| and |Vt′| increase. To enable to device to have good bipolar conduction characteristics when operating in the J region the maximum value of X is typically 1.5 microns.

The nominal operating voltage range of a circuit governs the range of Vce values that will be applied to the transistors within it. With Vce known, the spacing X for each transistor device 1 within the circuit can be selected when designing the circuit to determine whether it operates as a normally ON or normally OFF device.

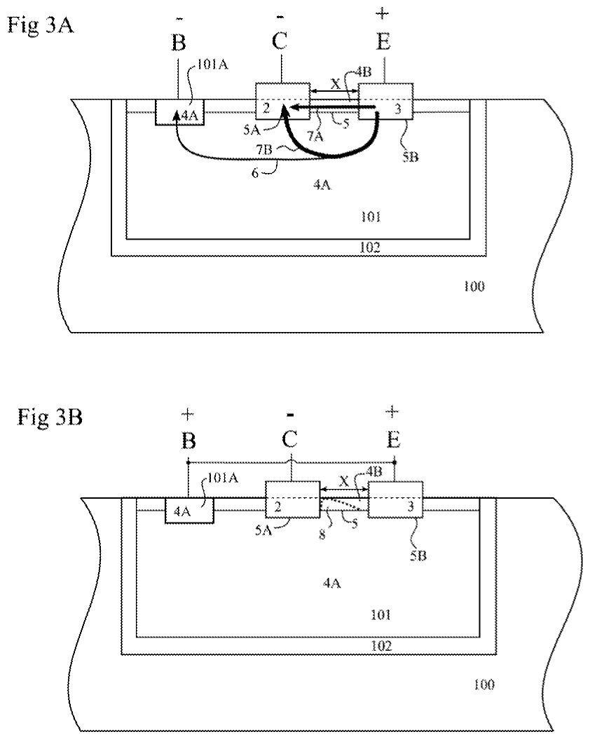

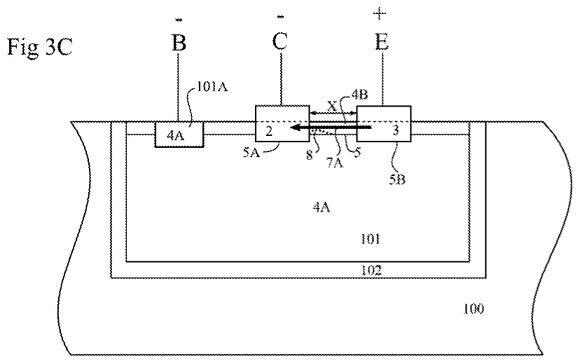

FIGS. 3A-3C illustrate the device of FIG. 1A with a lateral spacing X between the emitter and collector regions selected to be relatively large so that |Vce| is less than |Vt| and thus the device operates as a normally OFF transistor. In the present case the spacing X is such that Vce lies between Vt and Vt′ allowing the device to operate with the characteristics of any of regions J,K or L depending on Vbe.

FIG. 3A illustrates the normally OFF device operating in an ON majority bipolar condition (region J of FIG. 2). With the emitter terminal E at a relatively positive voltage compared with the base terminal B such that Vbe is more negative that Vft, the diode junction 5B between the emitter region 3 and sub-region 4A provided by N region 101 is forward biased allowing current flow (represented by arrow 6) through the diode junction 5B between the emitter terminal E and base terminal B. Consequently, there is a corresponding but much larger current between the emitter 3 and collector 2 attributed to both unipolar flow of charge carries through the channel 4B (represented by arrow 7A), and a yet larger current attributed to bipolar conduction via the N type base region 4A (represented by arrow 7B). The occurrence of unipolar conduction through the channel 4B provides the transistor with improved gain characteristics over transistors with conventional BJT structures.

Where the collector-emitter current is large, the bipolar current 7B may be significantly larger than the unipolar current 7A (e.g. on the order of 10× larger). This compares with a JFET where all (or close to all) of its current can be attributed to unipolar conduction through the channel.

FIG. 3B illustrates the device in an OFF condition represented by region K in FIG. 2. V_{CE} is identical to that shown in FIG. 3A but the base terminal B is floating or is tied to the emitter terminal E. As a consequence there is no current through the base terminal B.

This condition gives rise to a depletion region 8 shown notionally by the dotted line about the PN junction 5 which, because the channel 4B is very shallow and weakly doped compared with the base sub-region, pinches offs the channel 4B increasing the channel's 4B resistance to an extent that there is substantially no current between the emitter 3 and collector 2.

FIG. 3C illustrates the device operating in an ON majority unipolar condition (region L of FIG. 2) through applying a non-zero voltage Vbe across the emitter and base that is less than Vft. As Vbe is less than Vft, the diode junction 5B between the emitter 3 and N type base region 4A is not sufficiently forward bias to permit current through and so there is no current through the base terminal B or base region 4A; however, because of the channel's 4B very low net doping levels, Vbe is sufficient to reduce the depletion region 8 around diode junction 5 to an extent that allow for current through unipolar conduction between the emitter region 3 and collector region 2 via the channel 4B (represented by arrow 7A). Operating within region L, the transistor has a high gain characteristic by virtue that Ib=0A. However, because of the shallowness of the channel, the maximum current that can be obtained before the channel saturates is comparatively low compared with operation in the J region.

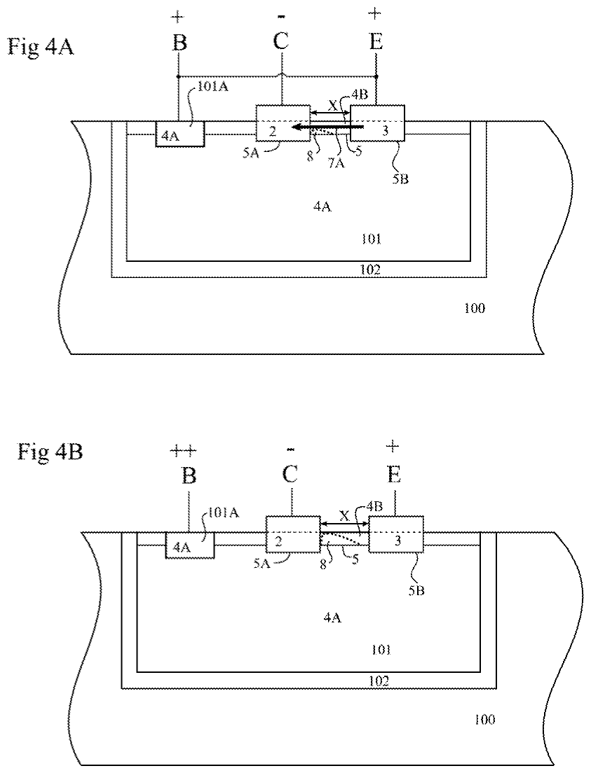

FIGS. 4A and 4B illustrate a variant device with an identical semiconductor structure to that of FIG. 1 except with a smaller spacing X between the collector region 2 and emitter region 3 and thus a shorter channel 4B. The spacing is selected such that when operated in a circuit that provides the same Vce range to the devices of FIGS. 3A-3C, Vce is greater that Vt and thus the device operates as a normally ON transistor.

It should be noted that although selecting the lateral spacing between the collector and emitter regions is the most convenient method to control the channel length, it may be possible to provide a longer channel length for a given lateral emitter-collector separation distance by forming the channel having a circuitous path between the emitter and collector regions.

FIG. 4A illustrates the device in an ON majority unipolar condition. V_{CE} is identical to that described in relation to FIGS. 3A-3C but due to the closer spacing X between the collector 2 and emitter 3, and thus the shorter channel 4B, it is sufficient to overcome the intrinsic depletion region around diode junction 5 even in the condition that the base terminal B is floating or is tied to the emitter terminal E. As a consequence, although there is no current through the base terminal B, there is a current between the emitter and collector via the channel 4A.

FIG. 4B illustrates the device in an OFF condition. This is achieved by making the base terminal B significantly more positive than the emitter terminal E.

Note that the surface area of the transistor, i.e., the dimension into/out of the page with respective FIGS. 1, 3 and 4 can be selected to increase the width of the base region including channel 4B, depending on the maximum current rating that the transistor device 1 is required to meet.

The substrate layer 100 may be connected to a low voltage to ensure that the PN junction between the substrate and the N+ layer 102 is reverse biased. This inhibits unwanted effects from parasitic lateral NPN BJT transistor between base regions of neighbouring transistors.

The N+ later 102 is required in part to prevent the P implant 103 from creating a short circuit between the emitter and substrate, and to ensure that the parasitic vertical PNP BJT formed between the emitter and the substrate has very poor current conduction characteristics, favourably reducing the parasitic current by a factor of more than 100 compared to the collector current of the device.

Alternative Embodiment With Variant Semiconductor Structure and Method of Manufacture

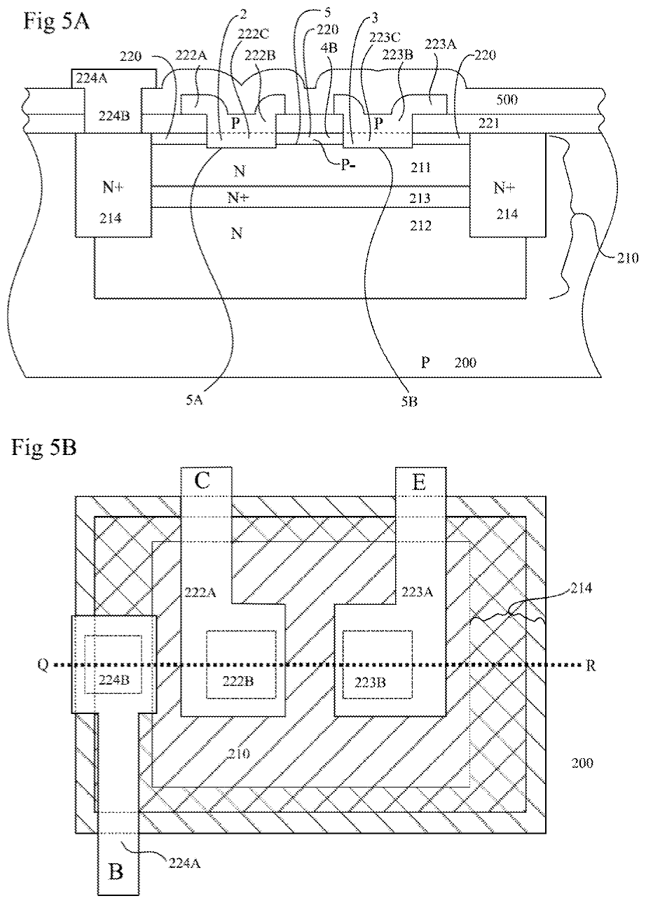

FIGS. 5A and 5B illustrate a variant semiconductor structure to implement the transistor device. The variant structure is advantageously easier to manufacture compared with that of FIG. 1. The dotted line QR represents the axis through which the section of FIG. 5A is taken.

There is provided a P type substrate 200, which may be, for example, a silicon wafer or layer deposited by epitaxy on top of the wafer. Within the substrate 200 is provided an N type well region 210 comprised from an upper N type region 211, a lower N type region 212 and an N+ type region 213 therebetween.

Surrounding the upper N type region 211 and N+ region 213 is a ring of a further N+ region 214. The N+ ring 214 overlaps with and extends outwards of the N Type well 210 to provide the N type region 4A of the transistor.

Lying above and in direct contact with the upper N type region 211 is a P-channel layer 220 that provides the channel 4B of the transistor. The P−channel layer lies in direct contact with the N type region 211 below it to provide diode junction 5.

Notably the N+ ring region 214 extends upwards, surrounding the P−channel layer 220 to isolate the channels 4B from the substrate.

The doping concentration of the N type region 211 is in the range of 1e17/cm3 to 5e17/cm3. This is in comparison to the high doping levels (>1e19/cm3) usually found in the gate of a JFET.

The P−channel layer 220 has a net doping concentration in the order of 1e16/cm3 to 1e17/cm3.

Lying over the P-channel layer 220 is an oxide layer 221. The structure also includes two separated P regions 222, 223 each extending through the oxide layer 221 and P−channel layer 220 to provide the respective collector and emitter regions 2, 3.

A first part 222A, 223A of each P region 222, 223 is provided by portions of a P doped polysilicon layer lying on the oxide layer 221 to connect the emitter and collector terminals into the circuit. A second part 222B, 223B of each P region 222, 223 is provided by portions of the polysilicon layer extending through the oxide layer 221 to contact the surface of the wafer. A third part 222C, 223C of each P region 222, 223 is formed in the silicon wafer and interfaces the N region 211 to provide respective diode junctions 5A 5B.

A patterned oxide layer 500 and a metal layer 224 lie over the oxide and polysilicon layers 221, 223. The portions 224A of the metal layer are patterned to provides conductive tracts. A second part 224B of the metal layer 224 extends through an aperture within oxide layers 500 and 221 to contact the N+ region 214 to provide the base terminal.

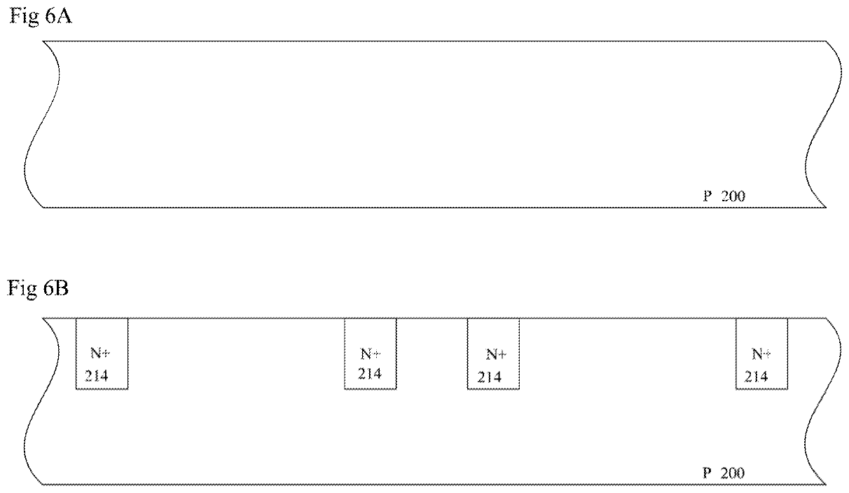

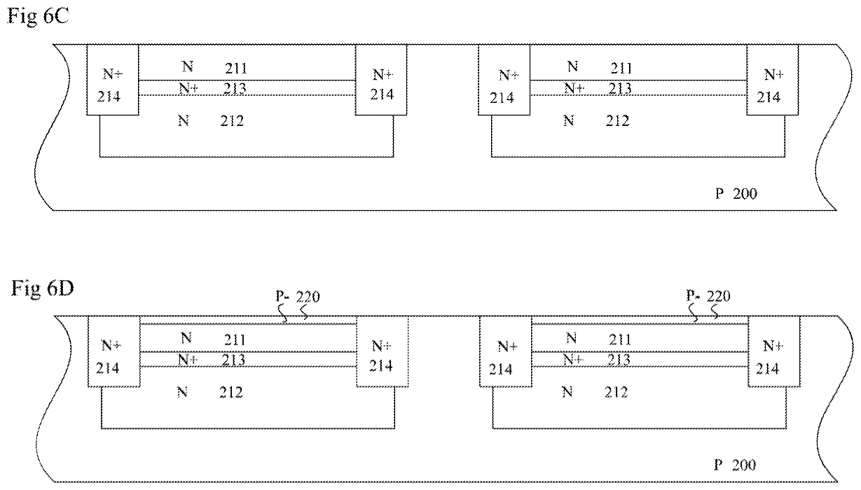

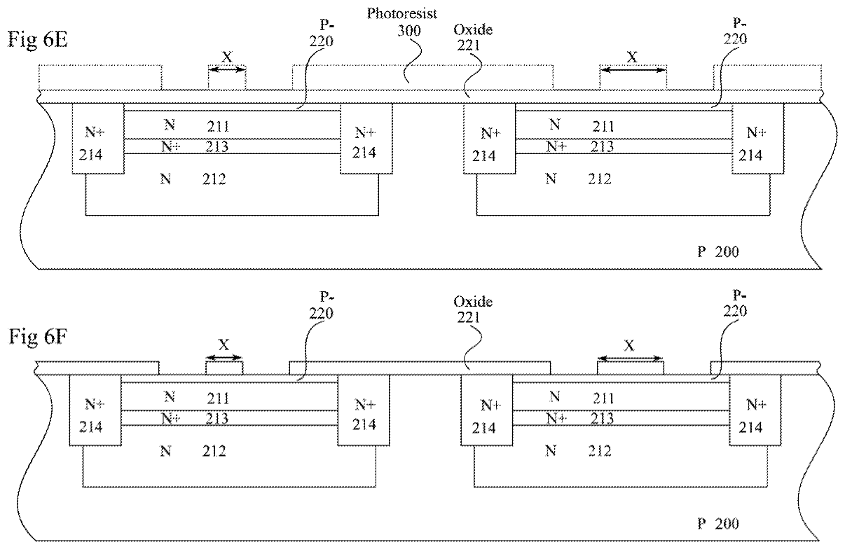

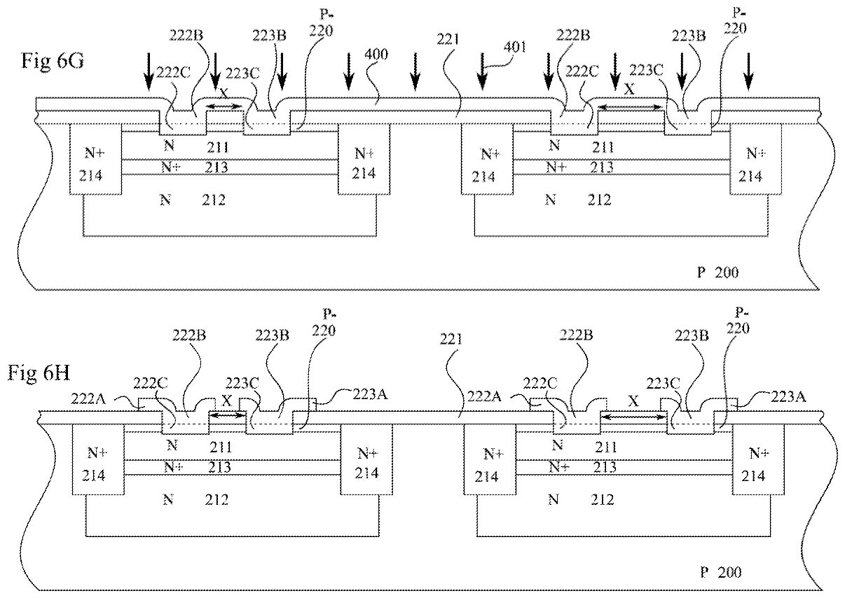

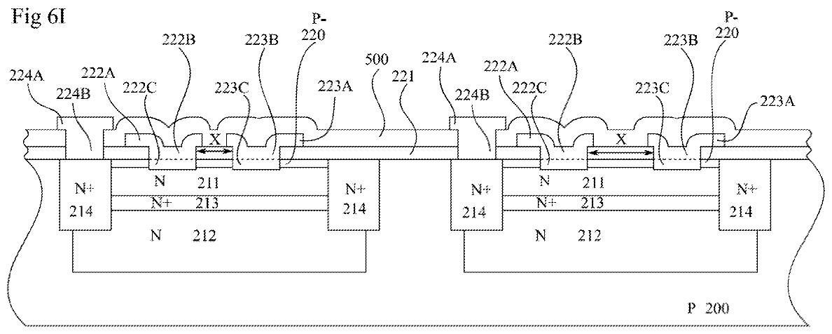

An example process for manufacturing two transistors with the structure of FIGS. 5A and 5B as part of an integrated circuit is illustrated with reference to FIGS. 6A-6I.

A first of the transistors is formed with a relatively small spacing X between the collector and emitter region and the other with a relatively large spacing, the spacing selected so that when in operation the first operates as a normally ON transistor and the other as a normally OFF transistor. The channel length of the second transistor may be selected such that it operates, when ON, with characteristics described in relation to either the L, N or J region of FIG. 2.

With reference FIG. 6A, a P type substrate 200 is provided. Turning to FIG. 6B, a mask, implant then diffusion process is used to form separate ring shaped (circular or otherwise) N+ regions 214, one for each transistor, in a P-type wafer 200.

With reference FIG. 6C, a mask and implant process is used to form the N type wells 210 within the respective rings 214. The diffusion process is omitted to leave the more highly doped N+ layer 213 beneath the surface, between N type layers 211, 212.

With reference FIG. 6D an unmasked P type implant process is used to form the P- channel layer 220. This may be carried out without a diffusion or anneal process. Because the doping required to form the P-channel region is so weak, the implant does not determinately affect the N+ regions.

With reference FIG. 6E, an oxide layer 221 is added to the wafer through a deposition process. Using a deposition process ensures the p−channel layer 220 is not harmed.

A photo resist 300 is applied over the oxide layer. The photo resist is patterned to define the spacing X between the collector and emitter regions and thus define the length of the channel 4B. The spacing X for the left hand transistor is, in this example, selected to be relatively small in order to provide a normally ON transistor, whereas the spacing X for the right hand transistor is selected to be relatively larger to provide a normally OFF transistor.

By way of example only for a 1 um fabrication process size, the right hand transistor may have a channel length between 1.2 microns and 1.5 microns. Whereas the left hand transistor may have a channel length equal to or less than 0.8 microns.

With reference FIG. 6F, the oxide layer is etched and the mask removed.

Referring to FIG. 6G, a layer of polysilicon 400 is deposited over (optionally the entire) wafer. The polysilicon layer 223 directly contacts the exposed surface of the P−layer 220 where the oxide layer 221 has been removed to form the collector and emitter contacts 222B, 223B.

A P type implant process 401 (represented by arrows) is carried out to convert the polysilicon to P type, the process also increases the net doping concentration of regions of the P−layer in direct contact with the polysilicon to form regions 222C, 223C of the collector and emitter terminals 2, 3. A short anneal step activates the implant without causing diffusion of the P−channel 220. Alternatively, in order to reduce the processing time a P-type polysilicon may be deposited.

Referring to FIG. 6H, the polysilicon layer 400 is masked and etched to pattern the collector and emitter terminals 2, 3 with tracks 222A 223A.

With reference to FIG. 6I, a further mask and etch process is used to expose a region of the N+ ring later 214 and metal 224 deposited to provide the base contact 224B, and etched with a pattern to provide routing layer 224A.

It will be appreciated that the device as variously described above could instead by implemented as a NPN device with an N-type channel, emitter and collector regions, and a P type base sub region. Where so the device will be operated with polarities reversed to that described above.

Rather than using a polysilicon layer, the emitter region and/or the collector region may be formed wholly within the wafer.

The above described structure could be altered to incorporate a zener diode that electrically connects between the base and collector terminals through the provision of an additional P region as described in WO2019/229432, hereby incorporated by reference.

The metal base contact could be replaced by a polysilicon doped contact. This would introduce a Zener diode into the base terminal, with the benefit of not requiring any metal layers to route close to the device.

The Abstract is provided with the understanding that it is not intended be used to interpret or limit the scope or meaning of the claims. In addition, in the foregoing Detailed Description, various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

The corresponding structures, materials, acts, and equivalents of all means or step plus function elements in the claims below are intended to include any structure, material, or act for performing the function in combination with other claimed elements as specifically claimed. The description herein has been presented for purposes of illustration and description, but is not intended to be exhaustive or limited to the examples in the form disclosed. Many modifications and variations will be apparent to those of ordinary skill in the art without departing from the scope of the examples presented or claimed. The disclosed embodiments were chosen and described in order to explain the principles of the embodiments and the practical application, and to enable others of ordinary skill in the art to understand the various embodiments with various modifications as are suited to the particular use contemplated. It is intended that the appended claims below cover any and all such applications, modifications, and variations within the scope of the embodiments.

Although specific embodiments of the subject matter have been disclosed, those having ordinary skill in the art will understand that changes can be made to the specific embodiments without departing from the scope of the disclosed subject matter. The scope of the disclosure is not to be restricted, therefore, to the specific embodiments, and it is intended that the appended claims cover any and all such applications, modifications, and embodiments within the scope of the present disclosure.

What is claimed is:

1. A transistor device having:
a collector region provided by a first region of semiconductor of a first type; a collector terminal associated with the collector region;
an emitter region provided by a second region of semiconductor of the first type; an emitter terminal associated with the emitter region;
a base region provided by a third region of semiconductor lying between and interfacing with both the collector region and emitter region; a base terminal associated with the base region;
wherein the base region includes:
a sub-region of semiconductor of a second type; and
a channel of semiconductor of the first type;
wherein the base terminal contacts the sub-region;
the sub-region interfaces with the channel to provide a first diode junction, and interfaces with both the emitter region and the collector region to form further diode junctions;
the channel interfaces with and interconnects the collector region and the emitter region such that when the device is implemented in a circuit in a first condition, namely where a voltage is placed across the emitter and collector terminals that is above a first threshold voltage, and the base terminal is floating or shorted to the emitter terminal, a current between the collector and emitter terminals is at least predominately attributable to unipolar conduction;
the net doping concentration of the channel is less than the net doping concentration of the emitter and collector regions; the channel has a depth extending away from the first diode junction which is sufficiently small that when the device is implemented in a circuit in a second condition, namely where the voltage placed across the emitter and collector terminals is below the first threshold voltage, and the base terminal is floating or shorted to the emitter terminal, a depletion region is formed about the first diode junction sufficient to pinch the channel so that substantially no current between the collector and emitter terminals of the device; and
there is a separation between the collector and the emitter that is sufficiently small that when the device is implemented in a circuit in a third condition namely, where there is voltage placed across the emitter and collector terminals, and there is a voltage across the emitter and base terminals such as to cause a base current through the base terminal, a current between the collector and emitter terminals is at least predominantly attributable to bipolar conduction.

2. A transistor device according to claim 1, wherein the separation between the collector and emitter regions is less or equal to 1.5 microns.

3. A transistor device of claim 1, wherein the channel has a depth extending from the first diode junction of less than or equal to 0.25 micron favourably less than or equal to 0.1 micron.

4. A transistor device according to claim 1, wherein the sub-region of the base region comprises a first portion and a second portion, and wherein:
the first portion has a higher net doping concentration than the second portion;
the base terminal electrically connects to the second portion through the first portion; and
in which the second portion interfaces with the channel to provide the first diode junction, and interfaces with both the emitter region and the collector region to form the further diode junctions.

5. A transistor device according to claim 4, wherein the net doping concentration of the channel is less than or equal to one times the net doping concentration of second portion of the sub-region.

6. A transistor device according to claim 5, wherein the net doping concentration of the channel is less than or equal 0.1 times the net doping concentration of the second portion of the sub-region.

7. A transistor device according to claim 6, wherein the second portion of the sub-region of the base has a net doping concentration of between 5e16/cm3 to 5e17/cm3.

8. A transistor device according to claim 7, wherein the first portion of the sub-region of the base has a net doping concentration greater or equal to 1e18/cm3.

9. A transistor device according to claim 1, wherein the sub-region is provided in a semiconductor substrate layer of the first type, and the device further comprises a highly doped region of the second type of semiconductor that lies between and separates the second part of the sub-region from the substrate; the highly doped region having a high net doping concentration compared with the sub-region.

10. A transistor device according to claim 1, wherein the emitter region and/or collector region are provided by a doped polysilicon layer provided on a silicon die that defines the base region.

11. An integrated circuit comprising two transistors according to claim 1, wherein the channel of a first of the transistors is relatively long and there is a relatively large lateral spacing between the collector region and emitter region of the first transistor, and the channel of the a second of the transistors is relatively short and the second transistor has a relatively small lateral spacing between its collector and emitter regions.

12. A method of operating the integrated circuit of claim 11, in which both the first and second transistors are operated within the same collector-emitter voltage range which is selected such that the first transistor operates as a normally on transistor and second transistor operate as normally off transistor.

13. A method of manufacturing an integrated circuit comprising two transistors of claim 1, the method comprising:
fabricating a first of the transistors to have a first lateral spacing between the emitter and collector regions of the first transistor, and fabricating a second of the transistors with a second lateral spacing between the emitter and collector regions of the second transistor, the first and second lateral spacing being different from each other.

14. A method according to claim 13, comprising:
using a same mask to define the spacing between the emitter and collector regions of both first and second transistors.

15. A method according to claim 14, comprising:
using the mask in a material removal process to define the emitter and collector regions of the two transistors.

16. A method according to claim 15, comprising:
depositing an oxide layer on the base region, using the mask to remove parts of the oxide layer, and depositing polysilicon in areas where the oxide layer has been removed to provide the collector and emitter regions.

17. A method of operating the transistor device of claims 1,
wherein when the device is ON |Vce|<|Vft|, and |Vbe|<=|Vce|;
where Vce is the voltage across the collector and emitter terminals;
Vft is the forward bias voltage of the base emitter diode junction; and
Vbe is the voltage across the collector and emitter terminals.

18. A method according to claim 17, wherein |Vce|≤½|Vft|.

19. A method according to claim 17, wherein when the device is in the OFF state:

|Vbe|<|Vft|.

20. A transistor device having:
a collector region provided by a first region of semiconductor of a first type; a collector terminal associated with the collector region;
an emitter region provided by a second region of semiconductor of the first type; an emitter terminal associated with the emitter region;
a base region provided by a third region of semiconductor lying between and interfacing with both the collector region and emitter region; a base terminal associated with the base region;
wherein the base region includes:
a sub-region of semiconductor of a second type; and
a channel of semiconductor of the first type;
wherein the base terminal contacts the sub-region;
the sub-region interfaces with the channel to provide a diode junction and the channel interfaces with and interconnects the collector region and the emitter region;
the net doping concentration of the channel is less than the net doping concentration of the emitter and collector regions; and
that the channel has a depth extending away from the diode junction which is sufficiently small that when the device is implemented in a circuit where a voltage is placed across emitter and collector terminals and the base terminal is floating, or shorted to the emitter terminal, a depletion region is formed about the PN junction sufficient to pinch the channel so that substantially no current flows between the collector and emitter terminals of the device.
